(19) United States
(12) Patent Application Publication
(10) Pub. No.: US 2017/0370993 A1
(43) Pub. Date: Dec. 28, 2017

(54) CONTROLLABLE LOAD SYSTEMS AND METHODS

(71) Applicant: AVTRON AEROSPACE, INC., Independence, OH (US)

(72) Inventor: RAYMOND G. WEINBERG, NORTH ROYALTON, OH (US)

(21) Appl. No.: 15/631,653

(22) Filed: Jun. 23, 2017

Related U.S. Application Data
(63) Continuation of application No. 62/354,368, filed on Jun. 24, 2016.

(51) Int. Cl. G01R 31/34; H02P 11/00

(52) U.S. Cl. CPC G01R 31/34; H02P 11/00

(57) ABSTRACT

An example system includes drive circuitry having outputs configured to provide drive current based on control parameters and having inputs configured to receive an output voltage of an electrical device. Simulation circuitry is configured to provide simulation signals based on the drive current and the output voltage. A controller sets the control parameters based on the simulation signals to control the drive circuitry to provide the drive current with an amplitude and phase to simulate a predetermined load condition for the electrical device.

### CROSS-REFERENCE TO RELATED APPLICATION

This application claims the benefit of priority from U.S. Provisional patent application No. 62/354368, filed Jun. 24, 2016, and entitled CONTROLLABLE LOAD SYSTEMS AND METHODS, which is incorporated herein by reference in its entirety.

### TECHNICAL FIELD

This disclosure relates to systems and methods for providing a controllable load, such as for use in testing electrical power devices.

### BACKGROUND

Generators and other electrical devices need to be tested to ensure that they operate properly. In the case of generator, this is usually done by connecting a load bank to the generator to provide loading that simulates the actual load conditions. However, loading a generator with a traditional load bank typically generates a lot of heat and wasted energy.

### SUMMARY

As one example, a system includes drive circuitry having outputs configured to provide drive current based on control parameters and having inputs configured to receive an output voltage of an electrical device. Simulation circuitry is configured to provide simulation signals based on the drive current and the output voltage. A controller sets the control parameters based on the simulation signals to control the drive circuitry to provide the drive current with an amplitude and phase to simulate a predetermined load condition for the electrical device.

As another example, a method includes receiving an output voltage supplied from an electrical device. The method also includes providing simulation signals based on the output voltage and drive current. The drive current is generated from the output voltage in response to control signals. The method also includes controlling the drive current based on the simulation signals to provide the drive current with a magnitude and phase to thereby simulate a predetermined load condition for the electrical device.

### BRIEF DESCRIPTION OF THE DRAWINGS

FIG. 1 is a block diagram showing an example of a controllable load system.

FIG. 2 depicts an example of a controllable load system connected to apply an electrical load to a generator test stand system.

FIG. 3 depicts an example of simulator circuitry.

FIG. 4 depicts an example of a phase locked loop frequency synthesizer that can be utilized in the simulator circuitry of FIG. 3.

FIG. 5 depicts an example of a control loop that can be utilized for controlling drive circuitry of the controllable load system.

FIG. 6 depicts the controllable load system utilized in a first example regenerative configuration in which the electrical energy is regenerated to a power bus.

FIG. 7 depicts the controllable load system utilized in a second example regenerative configuration in which the electrical energy is regenerated to an electrical power grid.

FIG. 8 depicts the controllable load system utilized in a third example of regenerative configuration in which the electrical energy is supplied to a brake resistor.

FIG. 9 is a flow diagram depicting an example method for controlling a load system.

### DETAILED DESCRIPTION

This disclosure provides controllable load systems and methods. These systems and methods provide electrical power loading of one or more devices under test according to a set of control parameters. The control parameters can set a target load condition that is to be applied to the electrical device under test. For example, the predetermined load condition may enable simulation of any combination of RLC (Resistance, Inductance and Capacitance) load.

As an example, a system includes drive circuitry having one or more outputs configured to provide drive current based on control parameters from a controller. Simulation circuitry is configured to provide simulation signals based on the drive current and a generator voltage produced by a generator (or other device under test). The controller sets the control parameters for the drive circuitry based on the simulation signals to control the drive circuitry to provide the drive current with an amplitude and phase to simulate a predetermined load condition for the generator. As mentioned, the load condition can be set (e.g., programmable in response to a user input) to establish the type and size of load being simulated.

In some examples, the systems and methods herein further may be implemented using COTS (Commercial Off-The-Shelf) AC motor drives as the loading device. The example systems and methods disclosed herein thus enable the drive to “think” it is connected to a motor and is controlling the motor, but in reality, provide the results of emulating a load bank to the generator. While this disclosure focuses on application of the systems and methods for testing generators, the concept is viable for a number of applications that employ a controlled electrical/electronic load having a predetermined load condition.

As a further example, the output from the drive circuitry may regenerate the electrical energy extracted from the generator directly to a power bus. In one example, a prime mover (motor) that is spinning the generator is connected to the power bus for immediate consumption of the regenerated energy by the prime mover. As another example, electrical energy extracted by the drive circuitry from the generator can be regenerated back to a Utility Grid. As yet another example, an all-in-one drive having an integrated controls and a brake resistor can be implemented efficiently using the controllable load system. For instance, the individual Resistive (R), Inductive (L) and Capacitive (C) load step elements can be replaced by a single braking resistor (BR) that is driven by the controllable load system.

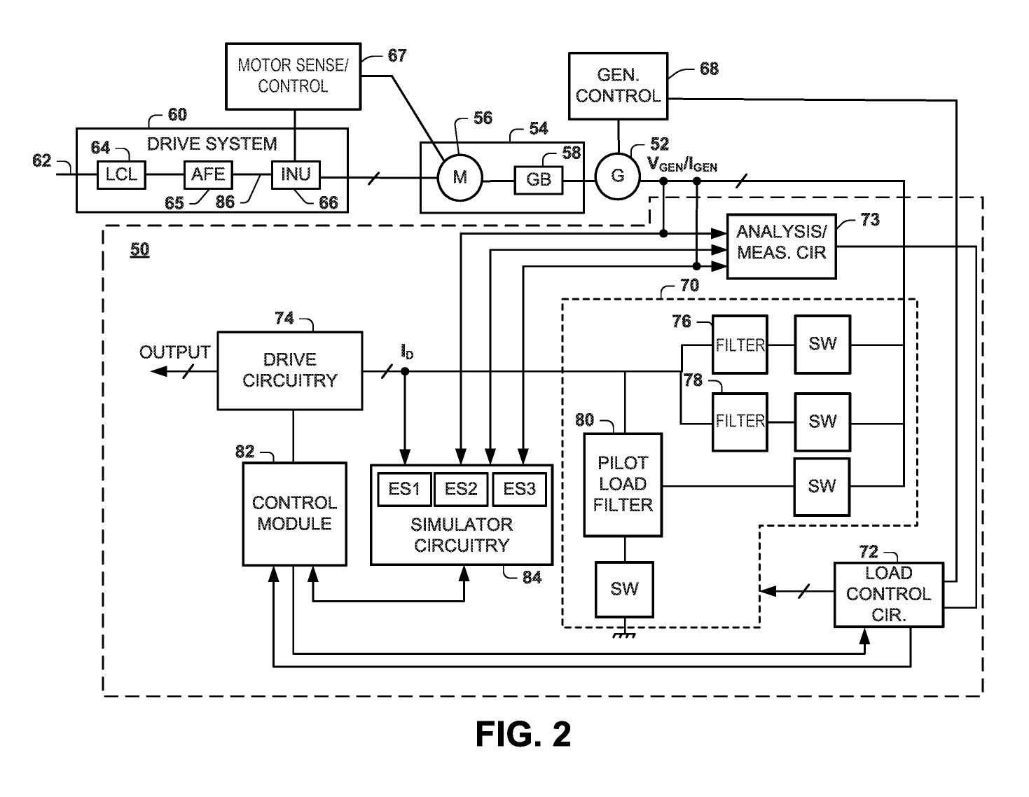

As used herein and shown in various figures (FIGS. 2-8), cross hashes are used to indicate that a given connection or bus may include any number of one or more transmission lines. That is, a given connection/bus with a cross hash may be a single line connection/bus, a double line connection/bus, a triple line connection/bus or have another number of transmission lines, which may depend on the particular application of the circuit and context in which it is being used.

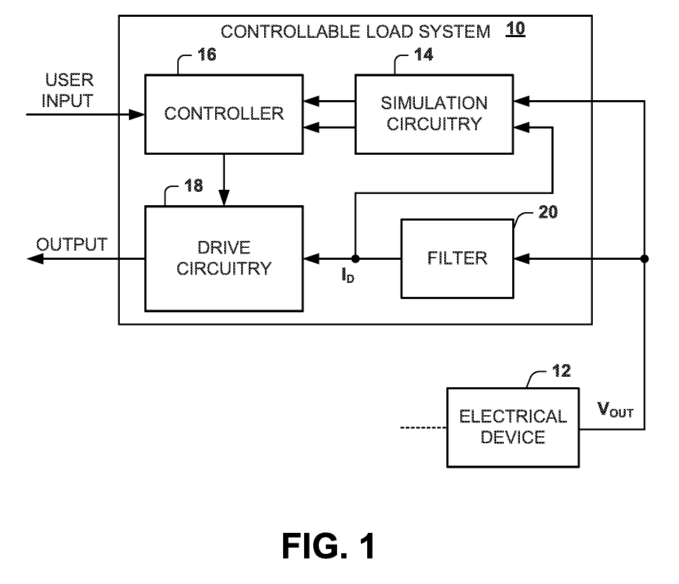

FIG. 1 depicts an example of a controllable load system 10. The controllable load system 10 is configured to simulate an adjustable load bank, such as can be utilized for testing an electrical device 12. In this example, the output voltage V_{OUT} of electrical device 12 is connected to an input of the controllable load system 10. In response to the output voltage V_{OUT}, the controllable load system 10 provides a corresponding output, which may be can be supplied to and/or utilized by one or more associated electrical devices in a desired manner.

In some examples, the electrical device 12 is a generator and the controllable load system 10 is connected to the generator as part of a motor-generator test stand system. For instance, the generator provides a generator output voltage (V_{GEN}) according to the configuration and control commands of the generator 12. The generator output voltage thus can supply power according to the capabilities and controls applied to operate the generator. While many examples herein are described in the context of using a generator as the electrical device 12 that is under test, other examples of the electrical device 12 include power amplifiers, inverters, batteries and battery chargers.

As an example, the controllable load system 10 includes simulation circuitry 14 that is configured to provide simulation signals generated based on the output voltage V_{OUT} and a drive current I_{D}. The drive current I_{D} corresponds to current provided by drive circuitry 18. For example, the simulation circuitry 14 provides the simulation signals as encoder output signals, such as simulating an incremental position of electromotive devices (e.g., motor and/or generator). In some examples, an encoder index may also be generated to simulate an absolute position, which may be used by the controller 16 to help synchronize the output voltage V_{OUT} and drive current I_{D} and/or set a desired phase offset.

For example, the drive circuitry 18 includes an arrangement of power switch devices, such as power metal oxide field effect transistors (MOSFETs), bipolar transistors, insulated gate bipolar transistors (IGBTs), thyristors or other switch devices. The power switch devices can be operated to implement an electrical power converter (AC power converter or DC power converter), such to provide DC-DC conversion, DC-AC conversion, AC-DC conversion or AC-AC conversion. The type and size of power switch devices and their operation may vary depending on application requirements. The drive circuitry 18 further may be implemented in a single-phase or a multi-phase configuration having one or more outputs, respectively, to provide the drive current I_{D} based on control parameters provided by the controller 16. In some examples, the drive circuitry 18 provides the drive current as the output with the same number of phases as output of the electrical device 12

The input to the drive circuitry 18, which corresponds to the drive current I_{D}, is connected to the output of the electrical device, corresponding to V_{OUT}, through a filter network 20. The filter network 20 may include one or more inductors to provide filtering as well as facilitate energy transfer from the device 12 under test through the drive circuitry. In other examples, the filter network 20 may include both inductors and capacitors or inductors, capacitors and resistors. Various filter topologies may be utilized according to the configuration of the electrical device and the output voltage V_{OUT}. The filter network filters the output voltage V_{OUT} to remove noise and reduce total harmonic distortion (THD), producing a filtered power signal corresponding to the drive current I_{D}. In addition to filtering and energy transfer, inductance in the filter network may also enable regeneration of low voltage to higher voltage buses. Moreover, depending on the filter topology, the filter network 20 may (or may not) introduce a phase offset between V_{OUT} and I_{D}. The filter network 20 may include one or more switch devices (e.g., contactors, relays or the like) to selectively configure the filter between the drive circuitry load system 10 and the output of the electrical device. For example, different filter components (inductors and/or capacitors) in the filter network 20 are selectively connected or removed in response to a command signal to achieve a desired filter response.

By way of example, the controller 16 utilizes the simulation signals from simulation circuitry 14 to control the drive circuitry 18 to provide the drive current with a desired magnitude and phase, such as corresponding to predetermined load condition for testing the electrical device 12. For example, the controller 16 synchronizes the drive current I_{D} with the output voltage V_{OUT} during an initial phase, such as by switching in a pilot load during this initial phase in the absence of actual loading the electrical device. After synchronization, the pilot load may be removed (or adjusted), and the controller 16 employs the simulation signals to control the drive circuitry 18 to provide drive current I_{D} to set the magnitude and phase to implement the predetermined load condition. In other examples, the pilot load can be omitted if instantaneous, non-commanded load phases can be tolerated by the electrical device 12 that is being loaded (e.g., generator) momentarily or if phase control circuitry is fast enough as not cause damage to the electrical device under test. The predetermined load condition may be a fixed or variable over time, such as one or more testing intervals. Additionally, the controllable load system 10 can be configured according to a simulating setting (in response to a user input) with appropriate load parameters for loading the electrical device 12 in a desired manner. The predetermined load condition can be set in response to a user input (e.g., input commands to set KVA, PF, etc.), such as entered via a human-machine interface that is connected to the controllable load system (directly or via a network connection).

As mentioned, the simulation circuitry 14 can include encoder simulation circuitry to monitor each of the drive current I_{D} and the output voltage V_{OUT}. The controller 16 can compare the encoder signals and determine a phase difference between the generator voltage V_{GEN} and the drive current I_{D}. Based on the determine phase difference, the controller 16 sets the control parameters for operating the drive circuitry 18 to provide corresponding magnitude and phase for the drive current I_{D}. The control parameters for the drive circuitry can depend on the type and quantity of predetermined load condition to which the load system 10 is to apply to the electrical device 12. The predetermined load condition may be programmed as load simulation settings, which can be utilized by the controller to emulate any load bank condition that is applied to the electrical device 12. For example, the predetermined load condition may be configured to set active power (Watts), reactive power (volt-ampere reactive (VAR)), complex power (VA), apparent power (magnitude of complex power) or a power factor (PF), corresponding to the ratio of active power to apparent power. The output of drive circuitry 18 thus can be connected to provide power to other circuitry or systems.

In some examples, such as disclosed herein, the controllable load system 10 can apply the predetermined load condition to the electrical device 12 while concurrently providing regenerative electrical energy to other circuitry or back to a power grid. Additionally or alternatively, the controllable load system 10 can apply the predetermined load condition to implement power factor correction. For example, the controllable load system 10 can be placed at or near the input power entrance to a building or other facility and apply loading to achieve total power factor correction for the building/facility. The controllable load system 10 disclosed herein can also more accurately implement for power factor correction since it is continuously variable/controllable, and does not require discrete component “steps” as in some existing approaches (e.g., capacitive load banks). Additionally, because of switch devices in the drive circuitry are independently controllable, the controllable load system 10 is able to “redirect” the energy between building facility inductances themselves—phase to phase energy transfer (Phase A inductance, Phase B inductance and Phase C inductance). As a result, the building inductances themselves can be used as the energy storage, which can eliminate (or at least significantly reduce) the need for other energy storage devices (e.g., capacitors) when used for power factor correction.

In some examples, such as where the electrical device 12 is a DC generator, the simulation circuitry 14 can be omitted from the system 10. In this example, the controller 16 can control the drive circuitry to set current, such as by implementing a DC current injection mode for motor braking. For example, two phases can be connected to one terminal and the other phase connected to the other generator terminal. The filter 20 includes an inductor between drive circuitry 18 and generator 12. The inductor provides filtering the switch action of the drive circuitry 18 as well as allows a lower generator voltage to be able to transfer energy to higher voltage DC bus (connected at the output of drive circuitry 18), utilizing inductance voltage kickback effect.

FIG. 2 depicts an example of a controllable load system 50 that is connected to apply a controllable load to a generator 52. The controllable load system 50 may correspond to the load system 10 of FIG. 1. In this example, the generator 52 is coupled to a drive stand 54 that includes a motor 56, which may be any prime mover. The drive stand 54 also may include a transmission, such as a gear box 58 that mechanically couples the motor 56 to drive (spin) the generator 52 under test.

The motor 56 drives the generator 52 in response to motor drive signals from the corresponding motor drive system 60. For example, the drive system 60 can be connected to a power grid at 62 to receive input power, such as corresponding to single or three-phase AC power. For example, the drive system 60 includes a filter 64 that is connected to each power input for the drive system. The filter 64 can be an inductor-capacitor-inductor (LCL) filter, for example. Filtered power signals provided to an active front end (AFE) 65 that, in this example, converts the filtered AC power to corresponding DC power at a DC bus. The AFE 65 can also include filtering and other circuitry to mitigate THD and noise in the DC power bus. The AFE 65 thus provides DC power to power electronics, such as an inverter unit (INU) 66. Other types of power converters may be used in other examples.

In this example, the INU 66 includes an arrangement of power switch devices configured to convert the DC power from the DC power bus. Each output of INU 66 is connected to provide corresponding AC drive current to the motor 56. The drive system can also include corresponding motor control electronics (e.g., hardware and software) 67 to control the INU 66 to set the magnitude and phase of the motor drive current. For example, the motor control 67 may employ a motor (absolute or incremental) encoder to convert the motors mechanical position into corresponding electrical signals (code) representing the angular motor position. Various types of encoders may be used (e.g., optical, mechanical, magnetic and capacitance encoders). As disclosed herein, the drive current can be three phase current supplied to the corresponding motor inputs for driving the motor and, in turn, the generator 52 via the gear box 58.

In response to driving the motor 56, the generator 52 spins to supply output power to an output power bus. The generator thus provides a generator output voltage (V_{GEN}) and output current (I_{GEN}), which defines the output power. Generator control electronics 68 can be provided to control the power that is generated, such as by varying current supplied to generator field. The load system 50 is coupled to apply electrical loading to the output power bus.

As a further example, a filter network 70 can be connected between the output of the generator 52 and drive circuitry 74 of the load system 50. The filter network 70 can correspond to the filter 20 of FIG. 1. The filter network 70 can apply filtering to the generator output voltage V_{GEN} and provide drive current I_{D} according to control parameters provided to the drive circuitry 74. The filter network 70 includes an arrangement of filters 76, 78 and 80 electrically connected between the generator 52 and the drive circuitry 74. Each filter 76, 78, 80 may include inductors and/or capacitors to provide corresponding filter functions. In examples, where a given filter 76, 78, 80 includes capacitive filtering, the phase of the drive current I_{D} will be different than the generator output voltage V_{GEN}. In examples filters 76, 78 and 80 introduce such phase difference, the control circuitry 88 can compensate for this difference such that PF (magnitude and phase) at the generator 52 is as desired.

In some examples, the filter network 70 includes switch devices (SW) arranged to selectively connect or disconnect the filters 76, 78 and 80 into and out of the controllable load system 50. For example, one or more switch devices SW can be connected to each output of the generator (e.g., in a three phase system) to selectively electrically connect a respective filter (or filters) in the electrical path between the output of the generator 52 and an input of the drive circuitry 74 of the load system 50. This can be used to configure the filters 76, 78 and 80 to a desired filter topology, such as by balancing performance tradeoffs between THD %, cost and size for different expected loading conditions. In other examples, the filters may be configured according to application requirements and the switch devices omitted from the filter network 70. The switch devices may be implemented as contactors or relays, for example.

In examples that include the switch devices SW, a load control circuit 72 can control the switch devices SW. For instance, the load control circuit 72 can activate and deactivate switch devices SW based on analysis of the generator (e.g., V_{GEN} and/or I_{GEN}) by analysis and measurement of generator operation, such as by analysis and measurement circuitry 73. Additionally or alternatively, simulator circuitry 84 further can provide information to the load control 72 for controlling the switch devices SW. While the analysis and measurement circuitry is shown separate from the load control circuit 72, in other examples, such circuitry may be combined. For instance, the functions of the load control 72, the analysis and measurement circuitry 73 and control module 82 may be integrated into a single control system. Such control system may be implemented as one or more modules in the drive stand 54 or at another location to provide corresponding sensing and control functions.

As a further example, one of the filters 80 may be implemented as a pilot load filter. The pilot load filter 80 is electrically connected between the generator 52, drive circuitry 74 and electrical ground via an arrangement of switch devices, such as shown in FIG. 2. Other configurations may be employed to utilize the filter 80 as a pilot load, such as prior to actual loading of the generator 52 by drive circuitry 74. For example, the load control 72 controls the associated switch devices during an initial start-up phase to selectively connect the filter 80 between V_{GEN} and I_{D} as a pilot load having a predetermined impedance (inductance and/or capacitance). During this initial phase, while the pilot load filter 80 is connected to the generator voltage via associated switch devices SW, a control module 82 employs simulation circuitry 84 to synchronize the drive current I_{D} with the generator voltage V_{GEN}. The pilot load filter 80 thus operates to reduce non-commanded, temporary difference in phase angle between output voltage V_{GEN} and current I_{D} in response to initial loading applied to the generator 52 by the controllable load 50. Once synchronization is achieved, the pilot load 80 may be disconnected from the generator voltage via load control circuit 72 and/or used in conjunction with other filters 76 and/or 78. Additionally, the control module 82 continues to maintain such synchronization and to control the drive circuitry 74 to provide any desired phase angle difference (or PF) during subsequent loading applied to the generator 52.

Thus, at this stage, the load control circuit 72 can selectively activate and deactivate appropriate switch devices SW to provide a desired filter topology using corresponding filters, 76, 78 and 80 and the control module 82 controls the drive circuitry based on simulation signals from simulator circuitry to set the magnitude and/or phase of the drive current I_{D} according to any predetermined load condition. While the load control circuit 72 is shown as being separate from the control module 82 in the example of FIG. 2, it will be understood that the load control and control module may be integrated on a common printed circuit board (PCB) or otherwise be co-located within a housing to provide control system functionality corresponding to both the control module and load control circuitry consistent with this disclosure.

In this example, the simulation circuitry 84 includes a drive current encoder simulator circuit (ES1) and a generator voltage encoder simulator circuit (ES2). The drive current encoder simulator ES1 is coupled to monitor the drive current to generate a set of encoder signals corresponding to the phase of the drive current I_{D}. The generator voltage encoder simulator circuit ES2 is coupled to monitor the generator voltage V_{GEN} and generates set of encoder signals corresponding to the phase of the generator output voltage V_{GEN}.

Each of the encoder simulator circuits ES1 and ES2 is configured to provide information simulating an angular position according to a code (e.g., binary code, gray code or the like) based on the drive current I_{D} and the generator voltage V_{GEN}. The simulated angular position information may be generated as a code simulating an incremental and/or absolute angular position. Each of the encoder simulator circuits ES1 and ES2 may provide respective simulation signals to the control module 82 via one or more corresponding interfaces. For example, the interfaces can correspond to I/O slots of the drive control module 82. The control module 82 is connected to supply drive signals to the drive circuitry 74 based on the simulation signals and other control parameters, which may be set by a user. As a result, the drive current I_{D} is provided by drive circuitry 74 with a corresponding phase and magnitude to thereby emulate a predetermined electrical load condition that is being applied to the generator 52.

As mentioned, for example, the magnitude and phase of the drive current I_{D} may be set by the control module automatically (e.g., at default or preprogrammed values) and/or set in response to a user input to provide the predetermined electrical load condition. For instance, a technician or administrator may employ a user interface to specify a desired KVA, KVAR, PF, or other desired load condition for the generator 52, which can be stored in memory (not shown). The control module 82 may implement a control loop to determine corresponding control parameters to control the magnitude and phase of the drive current I_{D} to apply the specified load condition to the generator. The load condition applied to the generator by the system 50 may remain constant during one or more consecutive test intervals or the load condition may vary over one or more test intervals.

The phase angle offset between the generator output voltage V_{GEN} and generator output current I_{GEN} may vary depending on the topology of the filter network 70 that is being used. Accordingly, in some examples, the simulator circuitry 84 also includes another encoder simulator ES3. The encoder simulator ES3 generates another set of encoder signals corresponding to generator output current I_{GEN}. For example, the analysis and measurement circuitry control system and/or circuitry 73 compares the simulation signals from ES2 and ES3, corresponding to the phase of V_{GEN} and I_{GEN}, to determine if it is set to desired/commanded value or if further control action is required. As another example, other circuitry (e.g., separate circuitry or part of the control module 82 or generator control 68) may be configured compare generator voltage and current signals directly and provide phase commands to drive the generator via advance/retard (or other similar) type commands. It should be noted that if the filter network 70 includes only inductors (e.g., line inductances) and no capacitors, the phase of the drive current I_{D} will be same as the phase of generator current I_{GEN}, such that the function of encoder simulator ES3 may be omitted or deactivated. Moreover, in other examples, consistent with this disclosure, variations and modifications may be made to eliminate one or more of the three encoder simulators ES1, ES2 and ES3.

In view of the foregoing example of FIG. 2, a basic approach is disclosed to use drive circuitry to emulate virtually any load bank for loading a generator or other source to with a predetermined load condition (e.g., desired KVA, KVAR, PF's, and the like). Various modifications to the drive circuitry may be implemented, for example, depending on the circumstances, such as programmability, budget considerations, etc.

As one example, when used in a drive stand (e.g., drive stand 54) already containing AC drives with a common DC bus link, the electrical energy extracted from the generator may be regenerated directly from the drive circuitry 74 to the common DC bus 86, such as for immediate consumption by the prime mover/motor 56 that is spinning the generator 52. As an alternative example, if the drive stand 54 does not already contain a common dc bus ac drive system, or is powered by an internal combustion engine or some other means, the energy extracted from the generator 52 can be regenerated back to the AC Utility Grid at 62. As yet another alternative, use of an all-in-one drive with integrated Brake Chopper Unit (BCU) and Brake Resistor (BR) will not allow for regeneration of the extracted energy. However, the controllable load system can be used to make a lower cost implementation of this load control system, because the individual resistive, inductive and capacitive load step elements, which are typically used, can be replaced by a single braking resistor (BR) that is coupled to receive the driver current I_{D} from the drive circuitry 74. Other uses of the controllable load system 50 may be implemented in other examples.

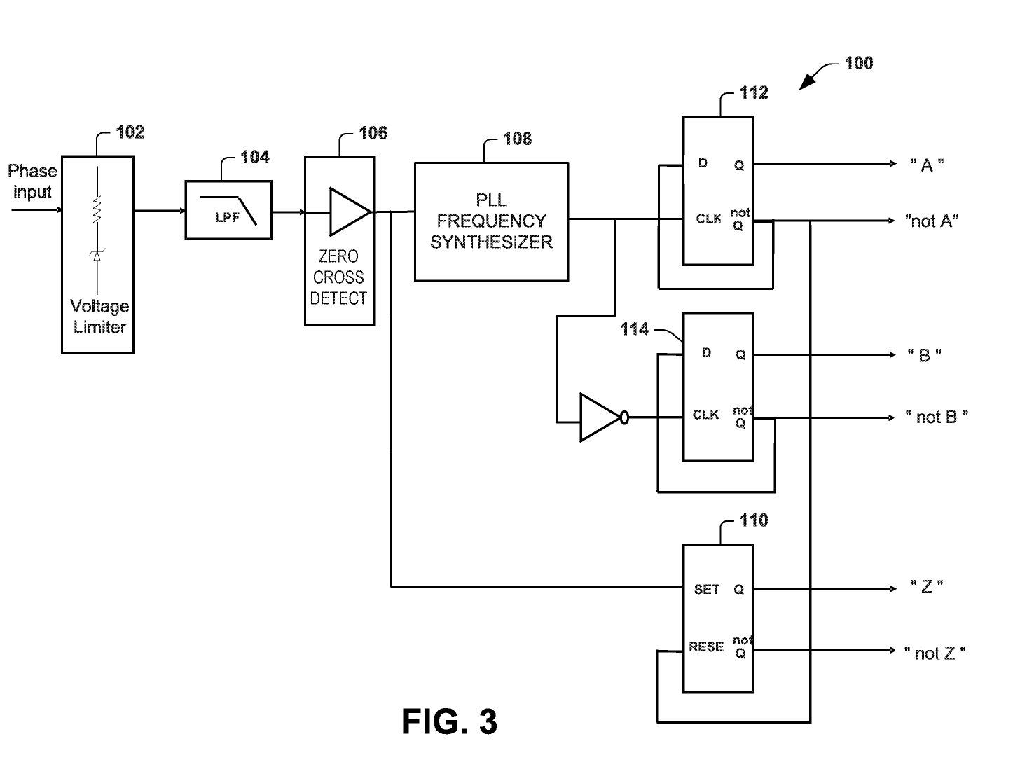

FIG. 3 depicts an example of an encoder simulator circuit 100, such as can be employed to implement ES1, ES2 or ES3 in FIG. 2. The circuit 100 thus can receive a current or voltage, such as corresponding to a given phase of the drive current I_{D} or generator voltage V_{GEN} or generator current I_{GEN}. A voltage limiting circuit 102 performs signal conditioning to normalize the input voltage or current to desired level for subsequent processing. Circuit 102 provides a voltage limited output to a low pass filter 104 to remove unwanted noise and high frequency components. A zero crossing detector 106 detects zero crossings of the filtered signal and provides a corresponding digital output representing each zero crossing instance. This may include crossings that occur on rising edge, a falling edge or both.

The detected zero crossings are provided as inputs to a phased-locked loop (PLL) frequency synthesizer 108. The PLL frequency synthesizer 108 is used to generate a higher frequency output than that of the fundamental frequency of the current or voltage input. The PLL frequency synthesizer 108 generates an equivalent PPR (pulses per revolution) such as having a frequency that is at least twice that of the input signal. Using higher PPR enables more precise phase angle resolution and control.

The output of the zero crossing detector 106 can also be provided to digital logic component (e.g., an output latch, such as a D flip-flop) 110 to capture the output of the zero crossing detector. Thus, digital output circuit 110 provides quadrature outputs, demonstrated as “Z” and “not Z”, in response to the zero crossing output. For example the “Z” and “not Z” outputs correspond to an index (marker) associated with the encoder signals.

The output of the PLL frequency synthesizer 108 drives additional digital logic (e.g., D flip-flops) 112 and 114. For example, the PLL output is provided to a clock input of latch 112 and to an inverter as to provide an inverted version of the PLL output to clock input of the latch 114. Latch 112 thus provides corresponding “A” and “not A” encoder simulation signals and latch 114 provides corresponding “B” and “not B” encoder signals.

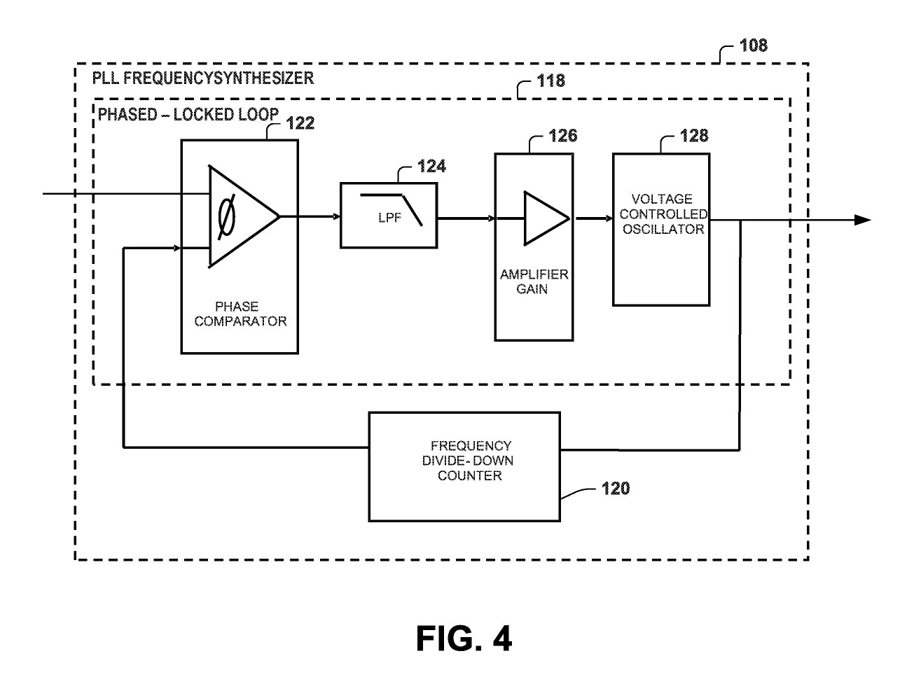

FIG. 4 depicts an example of a PLL frequency synthesizer that can be utilized as the PLL frequency synthesizer 108 of FIG. 3. For example, the synthesizer 108 can include a PLL 118 and a frequency divide-down counter 120.

The phase lock loop 118 thus receives an output of zero-crossing detector 106 at a phase comparator 122. An output of the frequency divide down counter 120 is supplied to another input of phase comparator 122 to provide a resulting comparison output, which is filtered by a low pass filter 124. The low pass filter 124 removes unwanted noise and provides a filtered version based on the phase comparison. The filtered signal is amplified by an amplifier 126 having a predetermined gain. The amplified signal is supplied to an input of a voltage control oscillator (VCO) 128 to provide the corresponding periodic signal, such as having a 50 percent duty cycle and a frequency that is set according to the amplitude of the amplified signal provided by amplifier 126.

In this way, the PLL synthesizer 108 generates a signal with an appropriate frequency to enable the encoder simulator circuit 100 to supply the set of signals “A”, “not A”, “B”, “not B”, corresponding to quadrature channels of an incremental encoder. The encoder simulator circuit 100 also may provide index signals, “Z” and “not Z”, corresponding to an index channel of encoder. As disclosed herein, each encoder simulator circuit thus provides simulated encoder signals indicative of the phase of the respective signals, including drive current I_{D} and the generator voltage V_{GEN} and, in some examples, generator current I_{GEN}. The controller (control module) thus can evaluate the simulator signals to control the drive current I_{D} to implement the predetermined load condition. For example, the drive control loop of controller (control module) monitors the quadrature signal set (“A”, “not A”, “B”, “not B”), while an overlying process monitors the index signals (“Z” and “not Z”), to implement phase angle offsets, as desired, to provide the predetermined load condition.

As a further example, the encoder simulator ES1, connected to the drive current I_{D} of the drive circuitry, provides a set of encoder simulation signals to the controller (control module). The encoder simulations signals from ES1, indicate the equivalent motor slip is zero and all the drive current I_{D} thus can be represented as the real component (as No Load Amps (NLA) or magnetization current) with Iq component (Torque Producing Current) equal to zero. As such, the drive current I_{D} can be set to any desired current level.

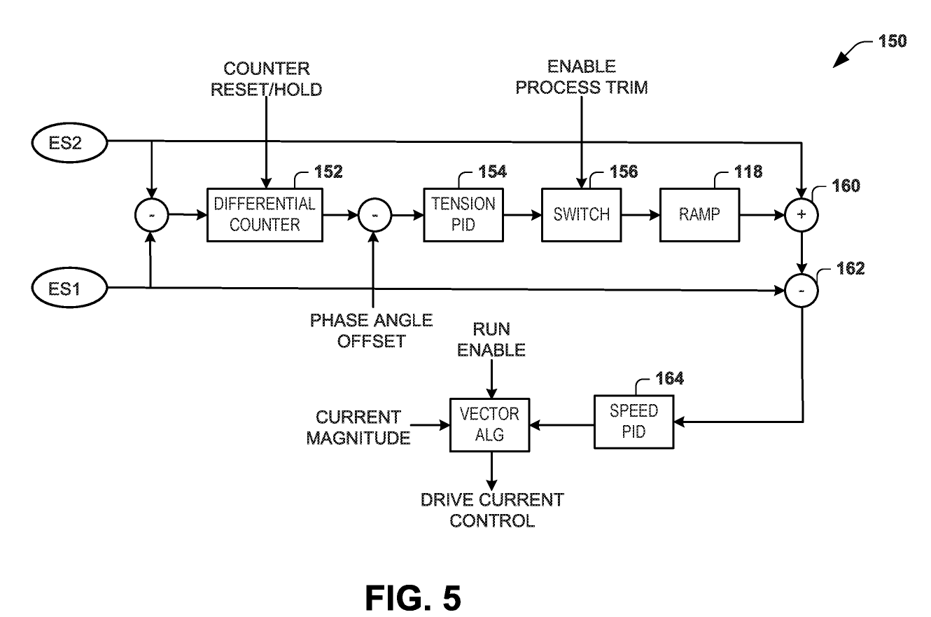

As a further example, FIG. 5 depicts an example of machine executable instructions (software) that can be executed by a controller (control module). As one example, the controller (control module) implements a tension control loop such as used for controlling slack in industrial processes. The encoder simulation signals (from ES1 and ES2) can be utilized by the tension control loop to provide respective slack-up and slack-out commands, which are used to set the relative offset in position between the drive current I_{D} and the generator voltage V_{GEN}, such as corresponding to the phase angle of the load being applied to achieve a desired load condition (e.g., power factor). In other examples the controller (control module) may implement other types of phase control loops to control the phase angle between the drive current I_{D} and the generator voltage V_{GEN}.

As shown in the example of FIG. 5, a difference between the encoder simulator outputs ES1 and ES2 can be determined and utilized to increment or decrement a differential counter 152. The differential counter may be reset or locked on in response to a counter reset/hold input. A difference between the differential count output value and the phase angle offset input can be determined and supplied to an input of a tension proportional-integral-differential (PID) loop 154. An output of the tension PID loop 154 can be provided as an input to a corresponding switch 156 for implementing process trim. The switch 156 can be enabled via a process trim enable input. In this case, the tension PID can be applied to a ramp signal, the result of which is supplied to an adder to combine with the ES2 input. The difference between this “trimmed” command reference and actual ES1 drive output can be computed by subtraction block 162 as a frequency error and supplied to input of speed PID 164. The speed PID 164 can supply a corresponding input to a vector algorithm. The vector algorithm also receives a current magnitude input to, in turn, generate a corresponding drive control signal for the drive current I_{D}. The drive circuitry in turn will supply drive current with a phase offset determined from on execution of the instructions 150 executed by the controller (control module).

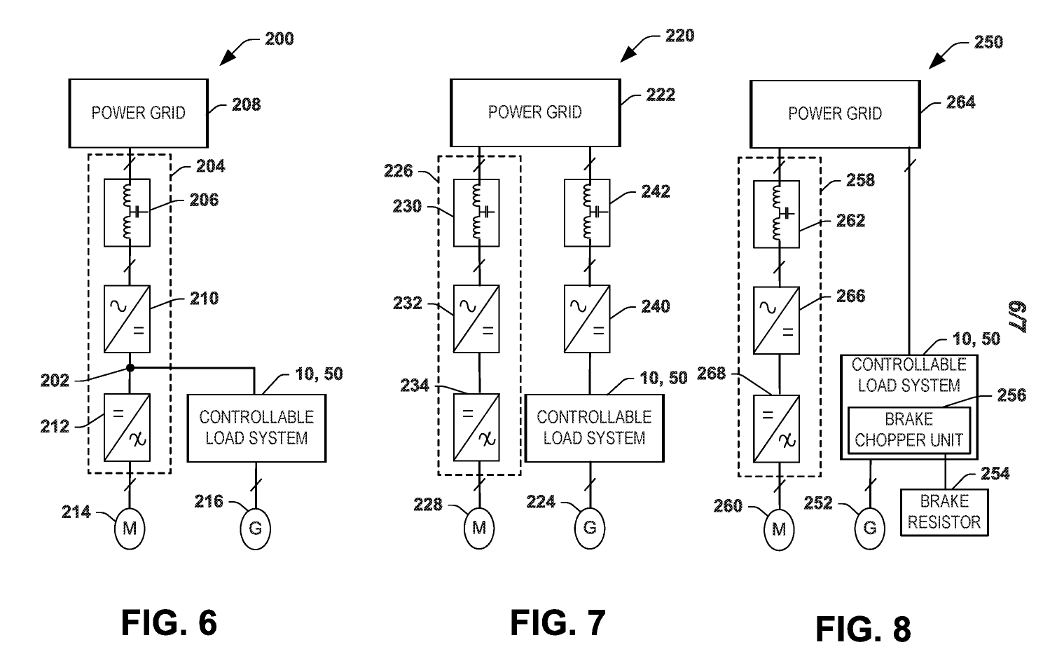

FIGS. 6, 7 and 8 demonstrate some alternative examples of different types of controllable load systems that can be implemented. Each of these types of controllable load systems can be implemented to provide a predetermined load condition, such as disclosed herein with respect to FIGS. 1-6 and 9. Accordingly, reference may be made to other figures herein for additional information.

FIG. 6 depicts an example of a system 200 that includes a controllable load system 10, 50 connected to provide electrical energy regeneration from a generator 216 back to a common bus (DC link bus) 202 of a motor drive system 204. The controllable load system 10, 50 may be configured to implement a DC load bank or an AC load bank that is applied to the generator 216 and regenerates to the bus 202. As one example, the controllable load system 10, 50 is implemented as AC-DC converter.

In this example, the motor drive system 204 includes a filter (e.g., an L-C-L filter) 206 that is connected to a power grid 208. The power grid 208 supplies single or multi-phase power to the drive system 204. An Active Front End 210 includes a power converter that converts the power grid electrical power to a desired level of DC electrical power, corresponding to the common bus 202. A drive circuit is controlled by a motor controller to supply electrical power (e.g., single or multi-phase current) from the common bus to drive a motor 214. While not shown, the motor 214 may be connected to spin the generator 216 through a gear box or other form of mechanical coupling. In some examples, a filter can be connected between the output of drive circuitry of the controllable load system 10, 50 and the generator 216 to smooth out the instantaneous current and voltage exertions away from the ideal, desired sinusoidal output. Proper choice of inductor and capacitor filter elements in the filter can allow this current to approximate sinusoidal with low THD. Again, the inductive component of the filter allows a lower voltage generator 216 to supply power to a higher voltage common DC bus 202.

FIG. 7 depicts an example of a system 220 that includes a controllable load system 10, 50 connected to provide electrical energy regeneration from a generator 224 back to a power grid 222 (e.g., an AC utility grid). The controllable load system 10, 50 may be configured to implement a DC load bank or an AC load bank that is applied to load the generator 224 and regenerates electrical energy back to the power grid 222. In this example, a motor drive system 226 is connected to drive a motor 228 that is mechanically coupled to drive a generator 224.

In this example, the motor drive system 226 includes a filter (e.g., an L-C-L filter) 230 that is connected to receive electrical energy from the power grid 222. The power grid 222 supplies single or multi-phase power to the drive system 226. An active front end 232 includes a power converter that converts the power grid power to a desired level of DC electrical power. A drive circuit 234 is controlled by a motor controller (not shown) to supply electrical power (e.g., single or multi-phase current) to drive the motor 228. In some examples, a filter can be connected between the output of drive circuitry of the controllable load system 10, 50 and the generator 224 to smooth out the instantaneous current and voltage exertions away from the ideal, desired sinusoidal output. Proper choice of inductor and capacitor filter elements in the filter can allow this current to approximate sinusoidal with low THD.

In this example, the controllable load system 10, 50 supplies its output DC power to an Active Front End 240. The AFE 240 includes a power converter that converts DC power to AC electrical power. The AFE 240 supplies the converted electrical power to a filter (e.g., an L-C-L filter) 242 that is connected to filter (remove switching frequency noise) from the regenerated electrical energy (power) that is supplied back to the power grid 222.

FIG. 8 depicts an example of another system 250 that includes a controllable load system 10, 50 connected to regenerate electrical energy from a generator 252 back to a brake resistor 254, such as to dissipate the energy as heat. The controllable load system 10, 50 may be configured to implement a DC load bank or an AC load bank that is applied to load the generator 252 and supply the electrical energy to brake resistor 254. In this example, the controllable load system 10, 50 may also implement a brake chopper unit 256. The brake chopper unit 256 can include one or more switching devices that are controlled to limit the voltage by switching the electrical power from the generator, as provided by the load system drive current, is diverted to the brake resistor 254. While the electrical energy is not regenerated or recaptured, as in the examples of FIGS. 6 and 7, the topology of FIG. 8 provides for a cost efficient solution and may afford improved performance over some existing approaches. This is because individual resistive, inductive and/or capacitive load elements, which are typically used, can be replaced by a single braking resistor 254.

The system 250 also includes a motor drive system 258 that is connected to drive a motor 260 mechanically coupled to drive the generator 252. The drive system 258 may be the same as in the examples of FIGS. 6 and 7. Briefly stated, the motor drive system 258 includes a filter (e.g., an L-C-L filter) 262 that is connected to receive electrical energy (single or multi-phase) from a power grid 264. An active front end 266 includes a power converter that converts the filtered electrical power to a desired level and type (AC or DC) of electrical power. A drive circuit 268 is configured to supply electrical power (e.g., single or multi-phase current) to drive the motor 260.

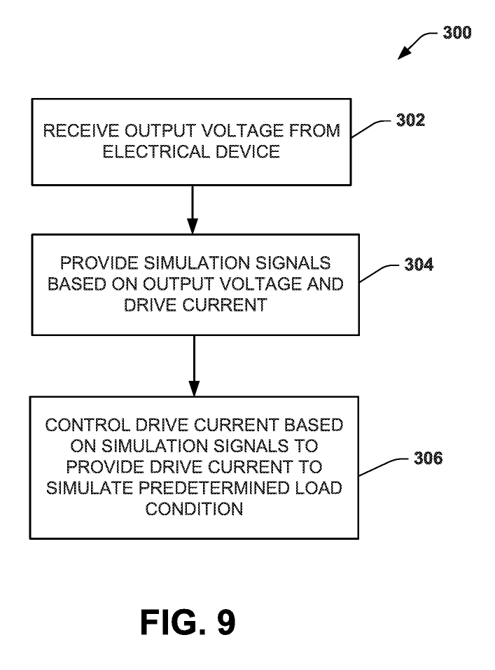

In view of the foregoing structural and functional features described above, an example method will be better appreciated with reference to FIG. 9. While, for purposes of simplicity of explanation, the method is shown and described as executing serially, it is to be understood and appreciated that the method is not limited by the illustrated order, as parts of the method could occur in different orders and/or concurrently from that shown and described herein. Such method can be executed by various circuit components and/or a control system executing machine readable instructions stored in memory, for example.

FIG. 9 is a flow diagram depicting an example method 300 for controlling a load system (e.g., system 10, 50). At 302, the method includes receiving an output voltage supplied from an electrical device (e.g., electrical device 12, generator 52). The output voltage may be a single phase or multi-phase voltage.

At 304, simulation signals are provided (e.g., by simulation circuitry 14, 84, 100) based on the output voltage and drive current. The drive current is generated from the output voltage in response to control signal (e.g., from controller 16, 82). For example, the electrical device is a power generator and the simulation signals include a simulated drive current encoder signal based on the drive current and a simulated generator voltage encoder signal provided based on the generator voltage. The simulated drive current encoder signal and simulated generator voltage encoder signal may be analyzed to control the phase of the drive current. In an example, the drive current is generated by drive circuitry comprising a plurality of switch devices (e.g., power converter).

At 306, the drive current is controlled (e.g., by controller 16, 82) based on the simulation signals to provide the drive current with an amplitude and phase to thereby simulate a predetermined load condition that is applied to the electrical device. As disclosed herein, the predetermined load condition may be set (e.g., to define an actual power, a reactive power, an apparent power and/or a power factor) in response to a user input. The controlling at 306 further may operate to synchronize the phase of the output voltage and drive current, initially, and once synchronized, impose a desired phase offset to simulate the desired load condition.

As disclosed herein, the method 300 may include filtering the output voltage, with filter circuitry (e.g., filter 20, 70), to provide a filtered power signal, and the drive current is generated from the filtered power signal. The filter may thus remove noise and reduce THD as disclosed herein. Additionally, drive current may be supplied to associated circuitry. For instance, while the phase of the phase of the drive current is set according to the predetermined load condition being simulated, a selected portion of the drive current (e.g., a selected percentage from 0%-100%) is diverted (e.g., by chopper unit 256) to a braking resistor (e.g., 254) to dissipate corresponding electrical energy (see, e.g., FIG. 6). In another example, the method may include regenerating electrical power provided by a generator (e.g., 12, 52) back to supply the regenerated electrical power to the motor (see, e.g., FIG. 7). In yet another example, the method may include regenerating electrical power provided by the generator back to supply the regenerated electrical power to an electrical power grid (see, e.g., FIG. 8).

In view of the foregoing, example systems and methods are disclosed to provide controllable loading for an electrical device under test. The approaches herein enable improved performance over existing approaches. This can be achieved for reduced initial investment compared to many existing load banks as well reduced costs during operation due to realized savings in electricity costs over time. Moreover, the controllable load systems and methods may be implemented in smaller spaces than traditional load banks. For the example of a typical aircraft generation system, a traditional load bank would fill a room, whereas a controllable load system configured according to this disclosure could be contained in a closet.

What have been described above are examples. It is, of course, not possible to describe every conceivable combination of structures, components, or methods, but one of ordinary skill in the art will recognize that many further combinations and permutations are possible. Accordingly, the invention is intended to embrace all such alterations, modifications, and variations that fall within the scope of this application, including the appended claims. Where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A system comprising:
drive circuitry having outputs configured to provide drive current based on control parameters and having inputs configured to receive an output voltage of an electrical device;
simulation circuitry configured to provide simulation signals based on the drive current and the output voltage; and
a controller that sets the control parameters based on the simulation signals to control the drive circuitry to provide the drive current with an amplitude and phase to simulate a predetermined load condition for the electrical device.

2. The system of claim 1, wherein the controller sets the control parameters to control at least one of a magnitude and a phase of the drive current according to the predetermined load condition.

3. The system of claim 2, wherein the predetermined load condition is set in response to a user input.

4. The system of claim 1, wherein the electrical device comprises a generator and the output voltage is a generator output voltage provided by the generator,
wherein the simulation circuitry comprises drive current encoder simulation circuitry to monitor the drive current and generator encoder simulation circuitry to monitor the generator output voltage.

5. The system of claim 4, wherein the controller compares encoder signals from the drive current encoder simulation circuitry and the generator voltage encoder simulation circuitry to determine a phase difference between the generator output voltage and the drive current, the controller setting the control parameters for the drive circuitry based on the determined phase difference.

6. The system of claim 5, wherein the controller includes memory that stores load simulation parameters to establish the predetermined load condition, the controller employing a control loop to set the control parameters for the drive circuitry according to the load simulation parameters.

7. The system of claim 6, wherein the predetermined load condition comprises a value representing at least one of an actual power, a reactive power, an apparent power or a power factor.

8. The system of claim 4, wherein the controller compares encoder signals from the drive current encoder simulation circuitry and the generator voltage encoder simulation circuitry to synchronize the phase of the drive current with respect to the phase of the generator output voltage in the absence of loading the electrical device.

9. The system of claim 1, further comprising filter circuitry electrically connected between the drive circuitry and an output of the electrical device corresponding to the output voltage.

10. The system of claim 9, wherein the filter circuitry comprises an inductive and capacitive filter.

11. The system of claim 1, further comprising a braking resistor coupled to the outputs of the drive circuitry, the controller controlling the phase of the phase of the drive current according to the predetermined load condition being simulated, and the controller including a brake chopper unit to divert a selected portion of the drive current to the braking resistor to dissipate corresponding electrical energy.

12. The system of claim 11, wherein the predetermined load condition comprises one of a resistive load, an inductive load or a capacitive load.

13. The system of claim 1, further comprising motor drive circuitry having an input coupled to a power bus and an output coupled to drive a motor that is connected to drive a generator, corresponding to the electrical device, wherein an output of the drive circuitry is connected to supply the drive current to the power bus of the motor drive circuitry, whereby electrical current provided by the generator is regenerated back to supply electrical power to the motor.

14. The system of claim 13, wherein the power bus is an AC power bus and drive circuitry is configured to supply AC power to the AC power bus, or the power bus is a DC power bus and the drive circuitry is configured to supply DC power to the DC power bus.

15. The system of claim 1, further comprising a loading system having an input to receive the drive current and an output to supply electrical power back to an electrical power grid.

16. The system of claim 15, wherein the loading system comprises:
an active front end circuitry coupled to the output of the drive circuitry; and
filter circuitry coupled between an output of the active front end circuitry and the electrical power grid,
wherein the drive circuitry is configured to provide the drive current as an AC current or a DC current.

17. The system of claim 1, further comprising a load bank coupled to the output of the drive circuitry.

18. The system of claim 17, wherein the load bank comprises a resistive energy dissipation unit that converts the drive current into heat, the drive circuitry implementing braking control that controls the drive current supplied to the resistive energy dissipation unit.

19. The system of claim 18, wherein the drive circuitry is configured to supply the drive current as an AC current or a DC current.

20. A method comprising:
receiving an output voltage supplied from an electrical device;
providing simulation signals based on the output voltage and drive current, the drive current being generated from the output voltage in response to control signals; and
controlling the drive current based on the simulation signals to provide the drive current with a magnitude and phase to thereby simulate a predetermined load condition for the electrical device.

21. The method of claim 20, further comprising setting the predetermined load condition in response to a user input, the predetermined load condition comprising at least one of an actual power, a reactive power, an apparent power or a power factor.

22. The method of claim 20, wherein the electrical device comprises a generator and the output voltage is a generator output voltage provided by the generator, the method further comprising:
generating a simulated drive current encoder signal based on the drive current;
generating a simulated generator voltage encoder signal based on the generator voltage;
analyzing the simulated drive current encoder signal and the simulated generator voltage encoder signal; and
setting at least one of the phase and magnitude of the drive current based on the analyzing.

23. The method of claim 22, wherein the analyzing further comprises comparing the simulated drive current encoder signal and the simulated generator voltage encoder signal to determine a phase difference between the generator voltage and the drive current, the at least one of the phase and magnitude of the drive current being set based on the determined phase difference.

24. The method of claim 20, wherein controlling the drive current further comprises synchronizing the phase of the drive current with respect to the phase of the generator voltage.

25. The method of claim 20, wherein filtering, with filter circuitry, the output voltage from the electrical device to provide a filtered power signal, the drive current being generated from the filtered power signal.

26. The method of claim 20, further comprising:
controlling the phase of the phase of the drive current according to the predetermined load condition being simulated, and
diverting a selected portion of the drive current to a braking resistor to dissipate corresponding electrical energy.

27. The method of claim 20, further comprising regenerating electrical power provided by a generator, corresponding to the electrical device, back to supply the regenerated electrical power to the motor.

28. The method of claim 20, further comprising regenerating electrical power provided by a generator, corresponding to the electrical device, back to supply the regenerated electrical power to an electrical power grid.

29. The method of claim 20, wherein the drive current is generated by drive circuitry comprising a plurality of switch devices.
